(19) United States
(12) Patent Application Publication
(10) Pub. No.: US 2019/0252230 A1
(43) Pub. Date: Aug. 15, 2019

(54) PLASMA RESISTANT ELECTROSTATIC CLAMP

(71) Applicant: Varian Semiconductor Equipment Associates, Inc., Gloucester, MA (US)

(72) Inventors: Dale K. Stone, Lynnfield, MA (US); Julian G. Blake, Gloucester, MA (US); Lyudmila Stone, Lynnfield, MA (US)

(21) Appl. No.: 16/397,324

(22) Filed: Apr. 29, 2019

Related U.S. Application Data
(62) Division of application No. 14/179,030, filed on Feb. 12, 2014.

(51) Int. Cl. H01L 21/683; H01J 37/32; H01L 21/67

(52) U.S. Cl. CPC H01L 21/6831; H01L 21/67109; H01J 37/32715

(57) ABSTRACT

An apparatus to support a substrate may include a base and an insulator portion adjacent to the base and configured to support a surface of the substrate. The apparatus may also include an electrode system to apply a clamping voltage to the substrate, wherein the insulator portion is configured to provide a gas to the substrate through at least one channel that has a channel width, wherein a product of the gas pressure and channel width is less than a Paschen minimum for the gas, where the Paschen minimum is a product of pressure and separation of surfaces of an enclosure at which a breakdown voltage of the gas is a minimum.

This application is a divisional of, and claims the benefit of priority to, U.S. patent application Ser. No. 14/179,030, filed Feb. 12, 2014, entitled “Plasma Resistant Electrostatic Clamp,” which application is incorporated herein by reference in its entirety.

### FIELD

The present embodiments relate to substrate processing, and more particularly, to electrostatic clamps for holding substrates.

### BACKGROUND

Substrate holders such as electrostatic clamps are used widely for many manufacturing processes including semiconductor manufacturing, solar cell manufacturing, and processing of other components. Many substrate holders provide for substrate heating as well as substrate cooling in order to process a substrate at a desired temperature. In order to maintain proper heating or cooling some substrate holder designs including those for electrostatic clamps provide a gas that may flow adjacent or proximate the backside of a substrate being processed, such as a wafer.

In particular substrate holder designs, such as in electrostatic clamps, gas may provided via a backside gas distribution system so that gas is present as a heat conductor between an electrostatic clamp surface and a back surface of a wafer that is held by the electrostatic clamp. In order to facilitate cooling or heating of a substrate the gas pressure may be maintained in a range to provide a needed heat transfer while not generating excessive pressure on the back surface of the substrate. Because a high electric field may be employed to clamping electrodes of the electrostatic clamp, the gas species may be affected when provided to the electrostatic clamp. In some circumstances this may lead to the generation of a plasma within a backside gas distribution system. The plasma species such as ions may etch surfaces that come into contact with the plasma, creating etched species that may be transported to other regions in a processing system, including to a substrate being held by the electrostatic clamp.

Although in some manufacturing processes the level of substrate contamination introduced by formation of plasmas within a backside gas distribution system may be acceptable, in other processes this may be unacceptably high. For example, when a substrate is processed at high substrate temperature, metal contaminants created in a backside plasma may be sufficiently mobile to reach the front of a wafer.

It is with respect to these and other considerations that the present improvements have been needed.

### SUMMARY

This Summary is provided to introduce a selection of concepts in a simplified form that are further described below in the Detailed Description. This Summary is not intended to identify key features or essential features of the claimed subject matter, nor is it intended as an aid in determining the scope of the claimed subject matter.

In one embodiment, an apparatus to support a substrate may include a base and an insulator portion adjacent to the base and configured to support a surface of the substrate. The apparatus may also include an electrode system to apply a clamping voltage to the substrate, wherein the insulator portion is configured to provide a gas to the substrate through at least one channel that has a channel width, wherein a product of the gas pressure and channel width is less than a Paschen minimum for the gas, where the Paschen minimum is a product of pressure and separation of surfaces of an enclosure at which a breakdown voltage of the gas is a minimum.

In another embodiment, a method of operating an electrostatic clamp may include arranging at least one channel of an insulator portion of the electrostatic clamp with a channel width, applying a clamping voltage to an electrode of the electrostatic clamp, an delivering a gas to the electrostatic clamp at a gas pressure through the at least one channel, wherein a product of the gas pressure and channel width is less than a Paschen minimum for the gas, where the Paschen minimum is a product of pressure and distance of an enclosure at which breakdown voltage of the gas is a minimum.

### BRIEF DESCRIPTION OF THE DRAWINGS

FIG. 1 depicts an electrostatic clamp system according to embodiments of the disclosure;

FIG. 2A depicts a side cross sectional view of an assembled electrostatic clamp according to various embodiments of the disclosure;

FIG. 2B depicts a top view of an insulator portion of the electrostatic clamp illustrated in FIG. 2A;

FIG. 2C depicts a top view of a base of the electrostatic clamp of FIG. 2A with the insulator portion removed;

FIG. 3A and FIG. 3B illustrate further details of a variant of the electrostatic clamp of FIG. 2A;

FIG. 4 is a graph that contains a curve showing breakdown voltage VB as a function of a pressure-distance (PD) product for a gas in a parallel plate system;

FIG. 5A shows a reference scenario for operating an electrostatic clamp;

FIG. 5B shows a scenario of operating an electrostatic clamp consistent with embodiments of the disclosure;

FIG. 5C shows another scenario of operating an electrostatic clamp consistent with other embodiments of the disclosure;

FIG. 5D shows a further scenario of operating the electrostatic clamp consistent with further embodiments of the disclosure;

FIG. 5E shows yet another scenario of operating an electrostatic clamp consistent with additional embodiments of the disclosure; and

FIG. 6 depicts a portion of another electrostatic clamp consistent with further embodiments of the disclosure.

### DETAILED DESCRIPTION

The present embodiments address a phenomenon that may adversely affect manufacturing of components that are sensitive to contamination. The embodiments described herein provide apparatus and methods for reducing inadvertent plasma formation in substrate holders such as electrostatic clamps. In particular, the present embodiments reduce likelihood of formation of backside plasmas that may be generated during operation of present day electrostatic clamps. These backside plasmas may cause etching of metal or other contaminants and recondensation of the contaminants on a back surface of a substrate, which may lead to detectable concentrations at the front surface of the substrate under certain process conditions. In the example of CMOS image sensor fabrication, levels of metal contamination as low as 1E8/cm-2 may impact device yield, which contamination levels may be produced when a plasmas forms in an electrostatic clamp adjacent the back surface of a substrate during processing of the substrate.

In some embodiments, a novel electrostatic clamp system is configured to reduce likelihood of plasma formation by alteration of the design of components such as a channel or channels in an insulator portion of the electrostatic clamp that supports a substrate. In some embodiments, a gas distribution system may alter the gas pressure provided in backside distribution channels in order to provide adequate gas pressure at the back of a substrate while at the same time generating gas conditions that avoid plasma formation within the backside distribution system. The gas distribution system may additionally alter the composition of gas provided to the electrostatic clamp to avoid plasma formation. In further embodiments, as detailed below, the frequency of an AC voltage applied to an electrode system in the electrostatic clamp may be adjusted to reduce plasma formation. In still other embodiments, in order to reduce probability of forming a plasma, an insulator portion of the electrostatic clamp may include a grounded conductor or low emissivity material within a channel that conducts gas to the substrate.

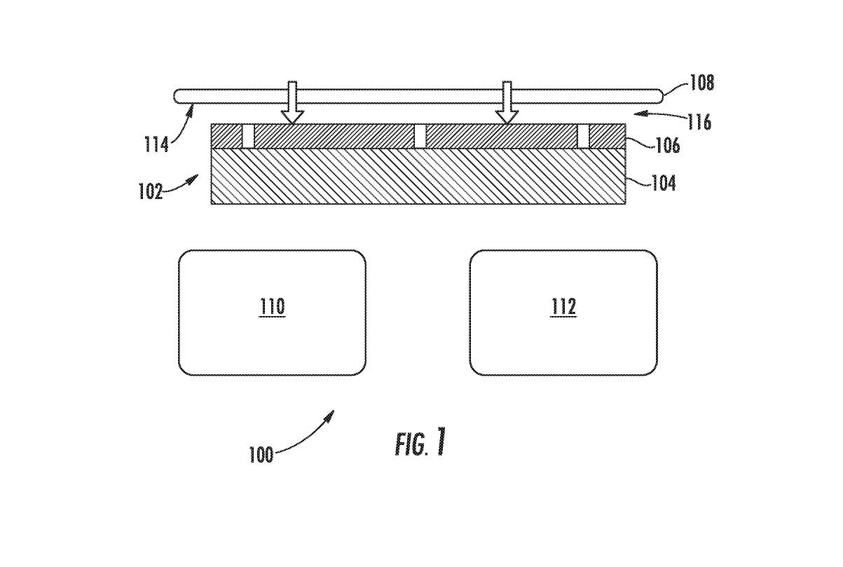

FIG. 1 depicts an electrostatic clamp system 100 according to embodiments of the disclosure. The electrostatic clamp system 100 may be suitable for use in various processing tools in which it may be desirable to provide active heating or cooling to a substrate. Such processing tools include ion implantation systems, deposition systems, etching systems, and annealing systems. The embodiments are not limited in this context however.

The electrostatic clamp system 100 includes an electrostatic clamp 102, gas supply system 110, and voltage supply 112. The electrostatic clamp 102 includes a base 104 and insulator portion 106 adjacent the base 104. The insulator portion 106 is configured to support a substrate 108, as illustrated. In various embodiments the insulator portion 106 may be a ceramic plate or ceramic layer. The voltage supply 112 is configured to supply a voltage to an electrode system (not separately shown) that is contained within the electrostatic clamp, which may generate an electric field that applies a clamping force to attract and hold the substrate 108. In various embodiments, as detailed below, the voltage may be applied as an AC signal in which image charge is rapidly created, thereby facilitating rapid chucking and de-chucking of the substrate 108. The voltage supply 112 may be configured to supply a bias voltage such as 1000 V in order to generate an appropriate clamping force to the substrate 108. This may generate an electrostatic clamp pressure on the order of 50 Torr to 200 Torr in some instances.

The gas supply system 110 is configured to supply a gas (not shown) to the base 104 of electrostatic clamp 102, which may be distributed to the substrate 108 in order to provide a heat-conducting medium between the electrostatic clamp 102 and substrate 108. In different embodiments, the gas that is supplied to the electrostatic clamp may be helium, neon, argon, nitrogen or other gas species or combination of gas species. The embodiments are not limited in this context. In order to supply sufficient heat conduction between substrate 108 and electrostatic clamp 102, the electrostatic clamp system 100 may be configured to deliver a gas pressure within the electrostatic clamp 102 of 10 Torr to 100 Torr, and in some instances 50 Torr to 100 Torr.

Consistent with various embodiments, the electrostatic clamp system 100 may be configured in different ways to avoid plasma formation in backside region 116. The backside region 116 may include channels within the electrostatic clamp 102 and cavities that are defined between the substrate 108 and electrostatic clamp 102 when the substrate 108 is held adjacent the insulator portion 106. As detailed below, the electrostatic clamp system 100 may provide immunity from plasma formation by adjusting the voltage signal applied to electrodes, adjusting the gas composition or adjusting gas pressure to avoid the Paschen minimum, adjusting cavity construction in the electrostatic clamp 102, or a combination of the adjusting voltage signal, gas pressure, or cavity construction. In some embodiments, the adjusting of cavity construction may include reducing the width of a channel or channels that conduct gas in the electrostatic clamp 102, by providing an electrically conductive channel coating that is grounded to form a grounded conductive layer within a channel or other cavity region of the electrostatic clamp 102, or by providing a low electron emissivity material in the channel or other cavity region.

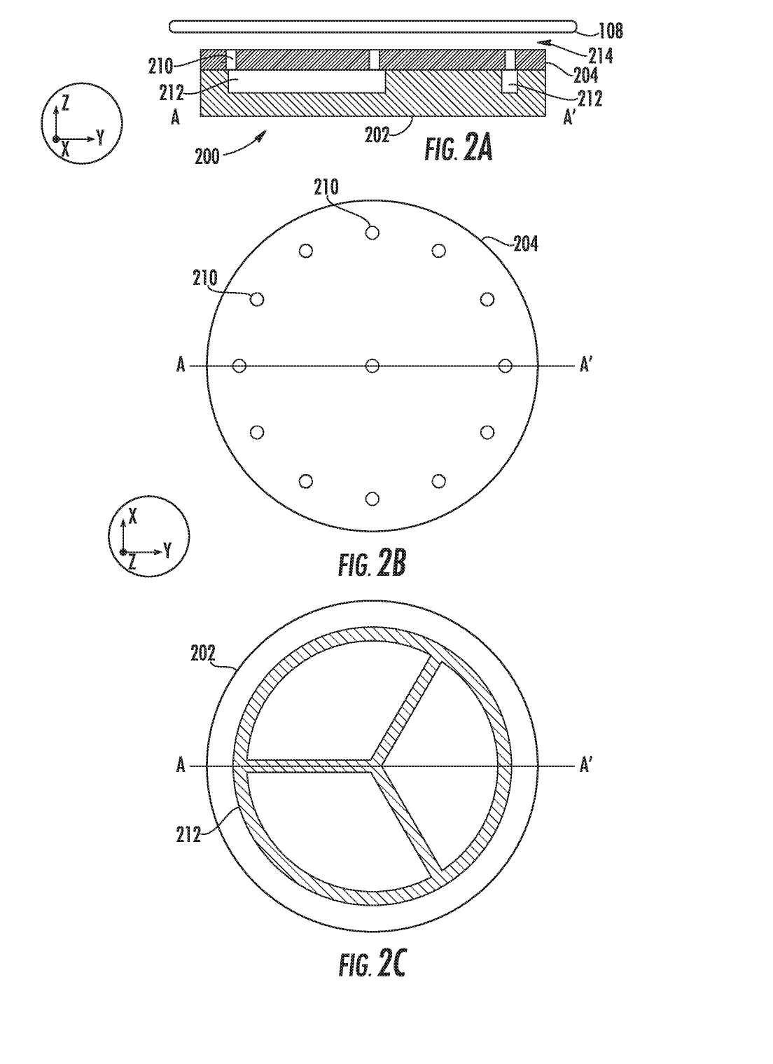

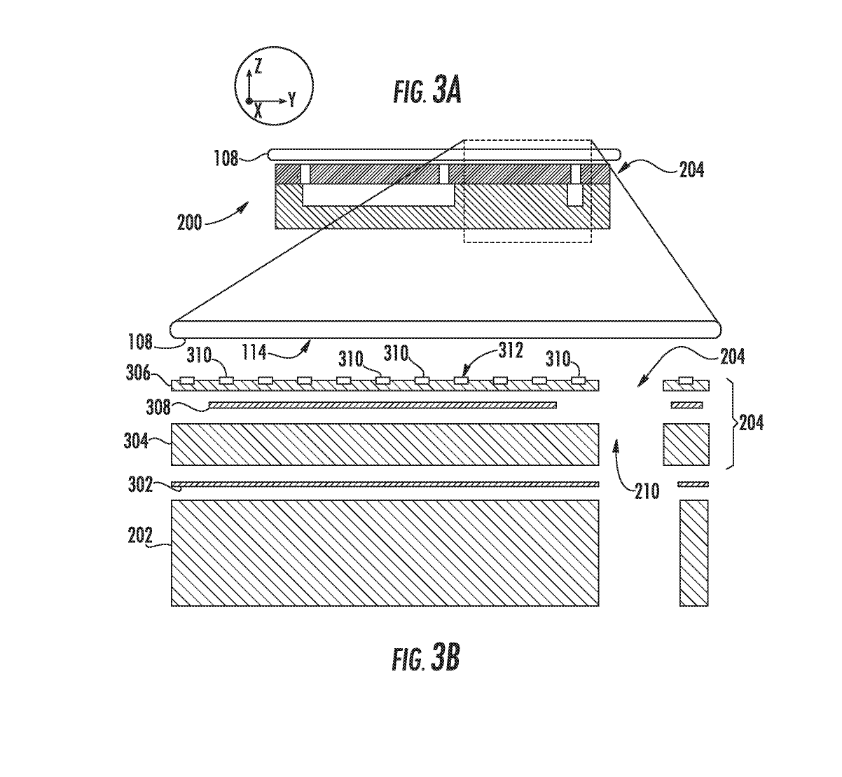

FIG. 2A depicts a side cross sectional view of an assembled electrostatic clamp 200 according to various embodiments of the disclosure. FIG. 2B depicts a top view of an insulator portion 204 of the electrostatic clamp 200, while FIG. 2C depicts a top view of a base 202 of the electrostatic clamp 200 with the insulator portion 204 removed. In various embodiments the base 202 may be a metallic material and may include a heater (not shown) that is designed to heat the electrostatic clamp 200. In other embodiments the electrostatic clamp 200 may be heated by a heater that is external to the electrostatic clamp or attached to the electrostatic clamp. As in the embodiment of FIG. 1, the electrostatic clamp 200 may support and hold the substrate 108 adjacent to the insulator portion 204. The insulator portion 204 may in turn include a set of electrodes (not shown) such as a set of electrode pairs that operate as in a conventional bipolar electrostatic clamp. The number of electrode pairs in the set of electrode pairs may be one, two, three, or greater.

In order to facilitate heat conduction between the electrostatic clamp 200 substrate 108, a gas may be provided to the electrostatic clamp 200. As illustrated in FIG. 2, the base 202 may include a gas distribution cavity 212 that is configured to distribute gas within different portions of the electrostatic clamp 200 in order to provide gas adjacent a back surface of a substrate. As illustrated in FIG. 2C the gas distribution cavity 212 may distribute gas circumferentially within the electrostatic clamp 200. However, in other embodiments a gas distribution cavity may have other shapes. As further shown in FIG. 2B the insulator portion 204 may include a set of channels, such as channels 210, which are configured to communicate with the gas distribution cavity 212 when the electrostatic clamp 200 is assembled. The channels 210 may serve to deliver gas to a backside region 214 between insulator portion 204 and substrate 108 when supplied with a gas using the gas supply system 110 shown in FIG. 1, for example.

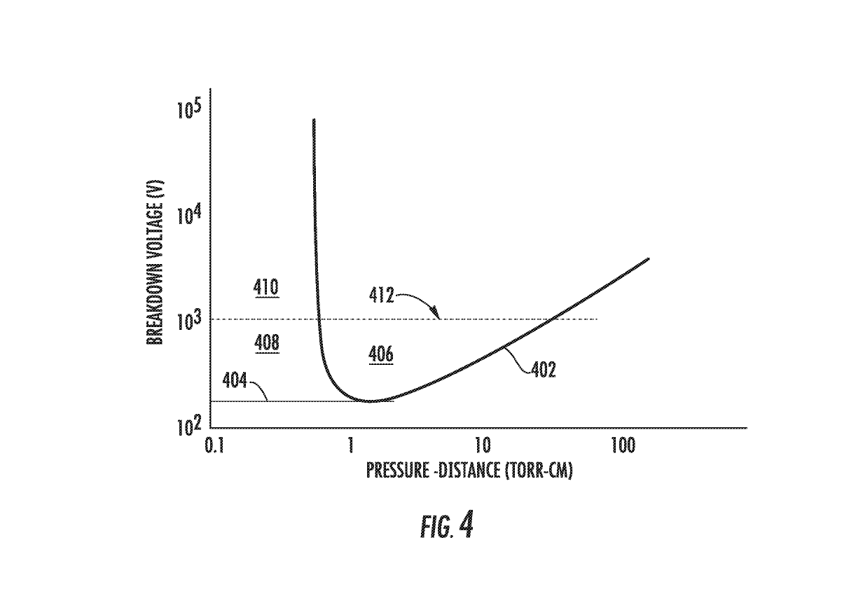

Consistent with various embodiments, the gas supply system 110 and channels 210 may be designed in particular to avoid plasma formation when clamping voltage is applied and gas is provided to the electrostatic clamp 200. Turning now to FIG. 3A and FIG. 3B, there are shown further details of a variant of the electrostatic clamp 200. In particular, FIG. 3B illustrates an exploded side cross-section of a portion of the electrostatic clamp 200. As illustrated, the base 202 may be coupled to the insulator portion 204 using a thermally conductive portion 302, which may be an adhesive such as epoxy. In this variant, the insulator portion 204 includes a first portion 304 that is adjacent the base 202 and a second portion 306 that is adjacent the substrate 108. An electrode 308 is disposed between the first portion 304 and second portion 306. When a voltage is applied between the electrode 308 and a paired electrode (not shown) a positive or negative image charge may develop on a region of the back surface 114 of the substrate 108. An opposite image charge on the back surface 114 may develop adjacent the paired electrode. This serves to generate a field that attracts the substrate 108 to second portion 306.

As further shown in FIG. 3B the second portion 306 includes surface features 310 that are raised with respect to a planar surface 312 of the second portion 306. This creates a cavity or cavities (not shown) into which gas may flow when the substrate 108 contacts the surface features 310 and gas is provided to the electrostatic clamp 200.

It is to be noted that when a high voltage is applied to the electrode 308, the field strength may be sufficient to generate a plasma in the backside region 214 if gas pressure of a gas directed into the electrostatic clamp 200 and cavity dimensions fall within certain ranges. Accordingly, in various embodiments, the dimensions of certain features within the electrostatic clamp 200 and gas pressure directed to the electrostatic clamp 200 are designed to avoid plasma formation. As detailed below, in particular embodiments, the dimensions of channel 210 and pressure of gas are designed so that the product of dimension and pressure do meet the Paschen minimum. In further embodiments, the composition of gas provided to an electrostatic clamp may be adjusted to reduce the probability of plasma formation in the backside region 214.

FIG. 4 is a graph that contains a curve 402 that illustrates Paschen curve behavior which denotes the breakdown voltage VB as a function of a pressure-distance (PD) product for gas in a parallel plate system. The curve 402 represents a composite of Paschen curves for different gases which behave according to the qualitative behavior shown in curve 402. In particular, below a value of PD product corresponding to the Paschen minimum 404, the breakdown voltage rapidly increases, meaning that breakdown requires rapidly increasingly higher voltages with decreased values of PD product below the PD product value of the Paschen minimum shown in curve 402. For many common gas species, such as Ar, He, Ne, and N2, a value of VB at the Paschen minimum ranges between 100 V and 500 V. Of these gas species, at the Paschen minimum, argon, neon and helium have measured to exhibit VB somewhat above 100 V to slightly above above 200 V. Argon also shows the lowest value of PD in the range of 0.7-2 Torr-cm. Nitrogen, which is commonly as a supply gas to electrostatic clamps, has been measured to exhibit a value of PD product in the range of 1 Torr-cm at the Paschen minimum, but exhibits a somewhat higher VB at the Paschen minimum in the range of 200 V to 400 V. The PD product at the Paschen minimum for neon and helium has been measured in the range of 1.5 and 2-4, respectively. However neon and helium each exhibit a breakdown voltage in the range of 200 V or below at the Paschen minimum. At higher values of PD product, the breakdown voltage increases in a linear fashion with the PD product, as shown in curve 402.

It is to be noted that present day electrostatic clamps may apply voltages of 1000 V (indicated by the line 412) or more to generate a desired clamping force for holding a substrate. Accordingly, using the example of clamping voltage of 1000 V, it can be seen from FIG. 4 that over a wide range of values of PD product, the value of VB may lie below the applied voltage, which is designated by region 406. This is true for the commonly-used nitrogen gas whose VB, although higher than common inert gases, may still be exceeded by voltage that is applied to an electrostatic clamp when gas pressure and cavity dimensions result in a PD product that is close to the Paschen minimum. It is further to be noted that present day electrostatic clamps are often designed to work under conditions in which the pressure applied to the wafer backside is in the range of 5 Torr to 15 Torr. This pressure range is convenient because it presents a gas pressure range in which good heat conduction may be achieved between electrostatic clamp and substrate, while presenting backside pressure that is sufficiently low that it can be countered by force generated by the voltage applied to the electrostatic clamp. For example, many electrostatic clamps may deliver a clamping pressure between 30-200 Torr.

However, this compromise between providing high enough backside pressure for good heat conduction between substrate and electrostatic clamp and low enough backside pressure to ensure proper substrate clamping comes at a cost. Present day electrostatic clamps often include gas distribution channels whose dimensions are susceptible to plasma formation at operating pressures and operating voltages that are applied to the electrostatic clamp. In particular, the channel width (D) may result in a PD product close to the Paschen minimum when gas is delivered to the electrostatic clamp. For example, it is common for channels to have widths in the range of three mm or more. In one instance, if 10 Torr pressure is delivered to the electrostatic clamp and the channel width is three mm, the value of PD product is 3 Torr-cm, which falls close to the Paschen minimum for gases such as Ar, Ne, and He, and lies within the region 406. When clamping voltage of, for example 500-1500 V, is applied to an electrostatic clamp that is operated under such design conditions, cavities such as channels within the electrostatic clamp may be especially susceptible to plasma formation.

Various embodiments overcome this problem by designing a combination of voltage signal, gas pressure and channel dimensions to avoid plasma formation. In particular, the combination of such factors may be such that the PD product falls in regions 408 or 410 of FIG. 4, where plasma formation is less likely.

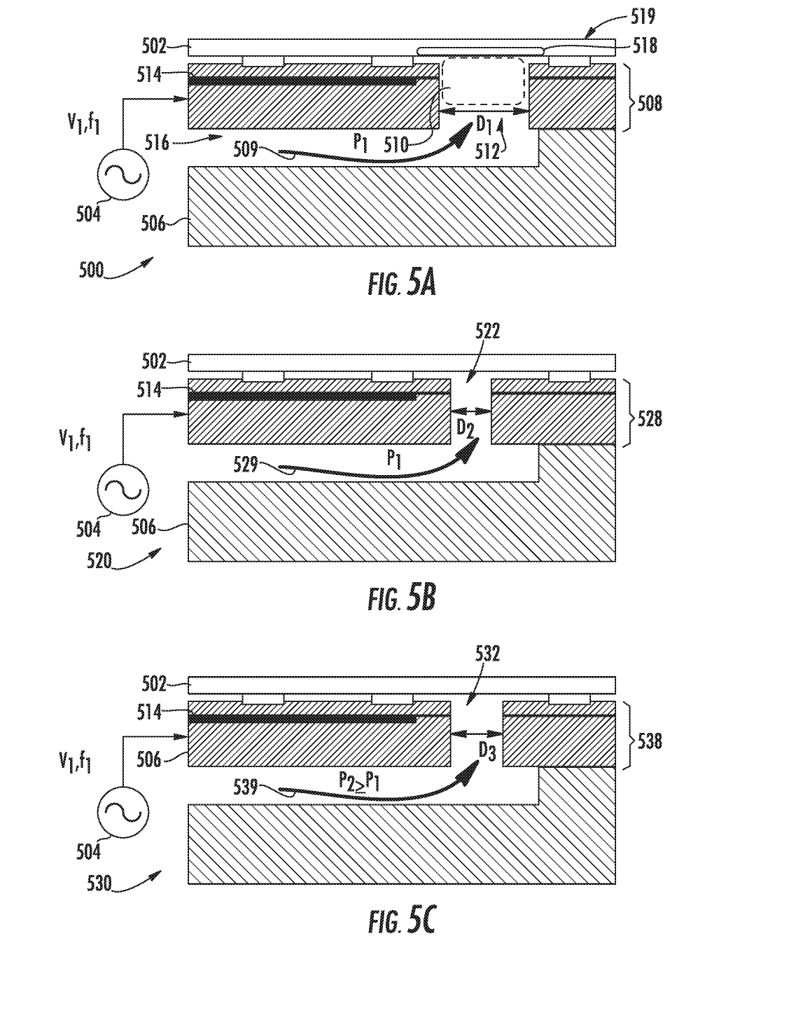

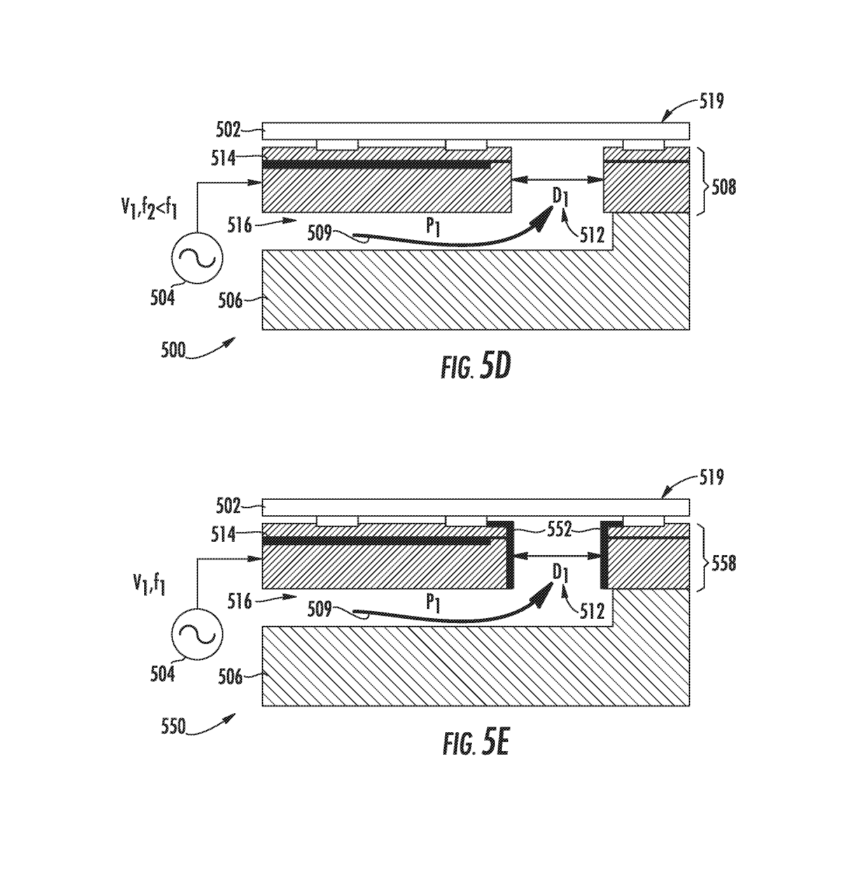

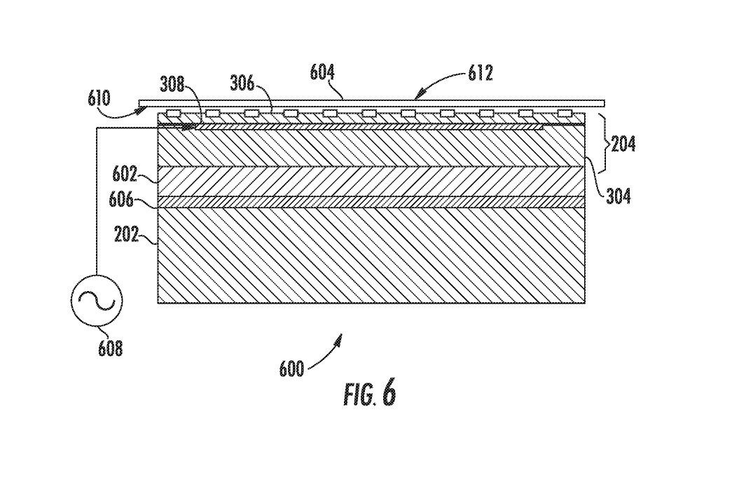

FIGS. 5A-5E illustrate principles for reducing plasma formation during operation of an electrostatic clamp according to various embodiments. In FIG. 5A there is shown a reference scenario for operating an electrostatic clamp. The electrostatic clamp 500 may hold the substrate 502 during processing as illustrated. Depending upon various factors, the electrostatic clamp 500 may be operated without formation of a plasma or may be susceptible to plasma formation. As shown in FIG. 5A, a gas is delivered to the electrostatic clamp 500 leading to the development of pressure P1. A voltage supply 504 is configured to apply a voltage V1 to the electrode 514, which may be applied as an AC signal at a frequency f1. In one example f1 is 25-30 Hz. When gas is provided to the gas distribution cavity 516 of base 506 the gas may enter channel 512 of insulator portion 508 before reaching the substrate 502. The channel 512 is characterized by a width D1, whose size may facilitate the formation of a plasma 510 as shown. When the plasma 510 strikes portions of the electrostatic clamp 500, such as the insulator portion 508 in the region of channel 512, material may be removed and may redeposit forming a contaminant region 518 on a portion of the substrate 502 as shown. Contaminants in the contaminant region 518 may subsequently diffuse to the front surface 519.

In FIG. 5B there is shown a scenario of operating an electrostatic clamp 520 consistent with embodiments of the disclosure that avoids plasma formation. In this embodiment the electrostatic clamp 520 includes an insulator portion 528 that has a channel 522 whose width D2 is smaller than the width D1. In some instances the width D2 is designed so that the channel 522 acts according to the principle of dark space shielding to prevent plasma formation. In particular, for a given gas pressure, if the dimension of a cavity to form a plasma are reduced below a certain size, formation of the plasma may be prevented. In some embodiments, the width D2 may be about 0.1-0.5 mm.

In FIG. 5C there is shown another scenario of operating an electrostatic clamp 530 that avoids plasma formation consistent with other embodiments of the disclosure. In this embodiment the electrostatic clamp 530 includes an insulator portion 538 that contains a channel 532 whose width D3 is smaller than the width D1. The width D3 is designed so that plasma formation in the channel 532 is avoided by producing a PD product that is further from the Paschen minimum as opposed to the example of FIG. 5A. In some embodiments, the width D3 may be about 0.1-1.0 mm. In various embodiments, as suggested by FIG. 5C, the pressure P2 delivered to the electrostatic clamp 530 may be greater than P1 to compensate for the smaller dimension of the channel 532 as opposed to the channel 512. The increased pressure may ensure that sufficient gas pressure exists adjacent the substrate 502 to provide a desired level of heat conduction between the electrostatic clamp 500 and substrate 502. In particular embodiments, the product P2D3 is less than P1D1 such that P2D3 is less than the Paschen minimum for a given gas 539. In this manner, the gas 539 may provide effective heat transfer between electrostatic clamp 500 and substrate 502 while remaining resistant to plasma formation in the channel 532.

In FIG. 5D there is shown another scenario of operating the electrostatic clamp 500, which avoids plasma formation in accordance with other embodiments of the disclosure. The electrostatic clamp 500 may be configured the same as that shown in FIG. 5A, except as otherwise noted. In particular, in this scenario the voltage supply 504 is configured to apply a voltage V1 to the electrode 514 as an AC signal at a frequency f2 where f2<f1. In one example f1 is a frequency of 15 Hz or less, such as 10-15 Hz. Even when the voltage V1 is applied to the electrode 514, a plasma may be prevented from forming due to the lower frequency of the voltage signal.

In FIG. 5E there is shown another scenario of operating an electrostatic clamp 550 that avoids plasma formation consistent with other embodiments of the disclosure. The electrostatic clamp 550 may be configured the same as electrostatic clamp 500 shown in FIG. 5A, except as otherwise noted. In particular, the electrostatic clamp 550 includes an insulator portion in which a grounded conductor may be disposed in cavity regions. For example, as shown in FIG. 5E, the grounded conductor 552 is disposed in the channel 512 and acts to prevent formation of an electric field in regions of the electrostatic clamp 550 including the channel 512, thereby preventing plasma formation when the gas 509 flows into the channel 512.

In additional embodiments, the gas supplied to an electrostatic clamp may be changed from nitrogen to other gases to reduce the likelihood of plasma formation. In one embodiment, He gas is supplied to the electrostatic clamp. Although He may exhibit a lower VB at its Paschen minimum, He exhibits a first ionization potential of around 25 eV as compared to 15 eV for nitrogen, thereby reducing the probability of forming a plasma in an electrostatic clamp at least under certain conditions. In further embodiments, a gas supplied to an electrostatic clamp may contain a mixture of gas species. For example, gas species such as NF3 of SF6, which each show a strong electron affinity, may be added to a gas such as N2 or an inert gas to generate a mixed species gas in which the NF3 of SF6 act as a quench of any plasma that may tend to form. The embodiments are not limited in this context.

FIG. 6 depicts a portion of another electrostatic clamp 600 consistent with further embodiments of the disclosure. In this embodiment the electrostatic clamp 600 is designed to heat a substrate 604 during implantation or other substrate processing. The electrostatic clamp 600 includes a heater 602, which may be a resistance heater in some embodiments. The heater 602 is embedded between the base 202 and insulator portion 204. As further shown in FIG. 6, a heat shield 606 may be embedded between the base 202 and heater 602 to reduce heating of the base 202 during operation of the heater. When the heater 602 is operational the electrostatic clamp 600 may be heated to elevated temperatures, in particular, those portions that lie above the heat shield 606. The insulator portion 204 may include those components as detailed above which serve to reduce the probability of plasma formation when a voltage is applied to the electrode 308 from voltage supply 608 and gas (not shown) is distributed to the electrostatic clamp. This helps to avoid chemical contamination of substrate 604 that may be caused by a plasma that may otherwise form in the electrostatic clamp 600. Such contamination is particularly difficult to control during an implant process or other process that employs the electrostatic clamp 600, because at elevated temperatures many chemical contaminants may diffuse from the back surface 610 of the substrate 604 to the front region 612 where active device layers may be present.

In additional embodiments, multiple features of a conventional electrostatic clamp may be adjusted to reduce plasma formation. In these embodiments, two or more features of a conventional electrostatic clamp may be adjusted to prevent plasma formation, such as adjusting at least two of: channel dimension in the electrostatic clamp, gas pressure, gas species, or addition of a grounded conductor to a channel. For example, a helium gas may be provided to an electrostatic clamp, for which the Paschen minimum lies in the region of 2 Torr-cm. The channel dimensions in an insulator portion, such as channel height or channel width, may be reduced to 0.1 mm, while pressure is adjusted to 75 Torr. This combination results in a PD product of 0.75, which is well below the region of the Paschen minimum for helium, making it unlikely for breakdown and plasma formation to take place.

In still further embodiments, an electrostatic clamp may include cavities that include a coating having a low secondary electron emission material to prevent plasma formation. Suitable materials for such coating include carbon, carbon nitride, and titanium nitride. The embodiments are not limited in this context.

The present disclosure is not to be limited in scope by the specific embodiments described herein. Indeed, other various embodiments of and modifications to the present disclosure, in addition to those described herein, will be apparent to those of ordinary skill in the art from the foregoing description and accompanying drawings. Thus, such other embodiments and modifications are intended to fall within the scope of the present disclosure. Furthermore, although the present disclosure has been described herein in the context of a particular implementation in a particular environment for a particular purpose, those of ordinary skill in the art will recognize that its usefulness is not limited thereto and that the present disclosure may be beneficially implemented in any number of environments for any number of purposes. Accordingly, the claims set forth below should be construed in view of the full breadth and spirit of the present disclosure as described herein.

What is claimed is:

1. A method of operating an electrostatic clamp, comprising:
arranging at least one channel of an insulator portion of the electrostatic clamp with a channel width;
arranging a substrate on the electrostatic clamp;
applying a clamping voltage to an electrode of the electrostatic clamp; and
delivering a gas to the electrostatic clamp at a gas pressure through the at least one channel, wherein a product of the gas pressure and channel width is less than a Paschen minimum for the gas, where the Paschen minimum is a product of pressure and distance of an enclosure at which breakdown voltage of the gas is a minimum.

2. The method of claim 1, wherein the clamping voltage is applied as an AC voltage having a frequency of 15 Hz or less.

3. The method of claim 1, wherein the channel width is 0.1 mm to 1 mm.

4. The method of claim 1, wherein the gas pressure is 50 Torr to 100 Torr.

5. The method of claim 1, wherein the gas comprises helium.

6. The method of claim 1, the electrostatic clamp comprising:
a base, adjacent the insulator portion;
wherein the insulator portion is configured to support a surface of the substrate; and
wherein the at least one channel comprises a carbon, carbon nitride, or titanium nitride.

7. A method of operating an electrostatic clamp, comprising:
arranging at least one channel of an insulator portion of the electrostatic clamp with a channel width;
arranging a substrate on the electrostatic clamp;
applying an AC clamping voltage to an electrode of the electrostatic clamp; and
delivering a gas to the electrostatic clamp at a gas pressure through the at least one channel, wherein a product of the gas pressure and channel width is less than a Paschen minimum for the gas, where the Paschen minimum is a product of pressure and distance of an enclosure at which breakdown voltage of the gas is a minimum.

8. The method of claim 7, wherein the AC clamping voltage has a frequency of 15 Hz or less.

9. The method of claim 7, wherein the channel width is 0.1 mm to 1 mm.

10. The method of claim 7, wherein the gas pressure is 50 Torr to 100 Torr.

11. The method of claim 7, wherein the gas comprises helium.

12. The method of claim 7, wherein the AC clamping voltage is arranged to generate a clamping force that exceeds the gas pressure.

13. The method of claim 12, wherein the gas pressure is between 10 Torr and 100 Torr.

14. The method of claim 12, wherein the AC clamping voltage ranges between 500 V and 1000 V.

15. The method of claim 7, wherein when the gas is delivered to the electrostatic clamp at the gas pressure, and the AC clamping voltage is applied at a frequency f2, a plasma forms in the electrostatic clamp, the method further comprising:
applying the AC clamping voltage at a frequency f1<f2, wherein at the frequency f1, and at the gas pressure, no plasma forms in the electrostatic clamp.

16. The method of claim 7, further comprising arranging a grounded conductor in the at least one channel of the insulator portion.

17. A method of operating an electrostatic clamp, comprising:
arranging at least one channel of an insulator portion of the electrostatic clamp with a channel width;
arranging a substrate on the electrostatic clamp;
applying a clamping voltage to an electrode of the electrostatic clamp, the clamping voltage generating a clamping force on the substrate; and
delivering a gas to the electrostatic clamp at a gas pressure through the at least one channel,
wherein a product of the gas pressure and channel width is less than a Paschen minimum for the gas, where the Paschen minimum is a product of pressure and distance of an enclosure at which breakdown voltage of the gas is a minimum,
and wherein the clamping force exceeds the gas pressure.

18. The method of claim 17, wherein the gas pressure is between 10 Torr and 100 Torr.

19. The method of claim 17, wherein the clamping voltage ranges between 500 V and 1000 V.

20. The method of claim 17, wherein the clamping voltage comprises an AC clamping voltage, wherein when the gas is delivered to the electrostatic clamp at the gas pressure, and the AC clamping voltage is applied at a frequency f2, a plasma forms in the electrostatic clamp, the method further comprising:
applying the AC clamping voltage at a frequency f1<f2, wherein at the frequency f1, and at the gas pressure, no plasma forms in the electrostatic clamp.
